(19) United States
(12) Patent Application Publication
(10) Pub. No.: US 2012/0298394 A1
(43) Pub. Date: Nov. 29, 2012

(54) ANTI-SHEDDING STRUCTURE FOR TABLET PC

(76) Inventor: Pei-Lin HUANG, New Taipei City (TW)

(21) Appl. No.: 13/564,544

(22) Filed: Aug. 1, 2012

Related U.S. Application Data
(63) Continuation-in-part of application No. 13/041,530, filed on Mar. 7, 2011.

(51) Int. Cl. H05K 5/00

(52) U.S. Cl. 174/50

(57) ABSTRACT

An anti-shedding structure for a tablet PC comprises: a protecting case, having a bottom, the edge or corners of the bottom having plural fastening portions, the edge of the protecting case having a connecting portion, the shape of the inner surface of the connecting portion fitting the shape of the back surface of the tablet PC, the connecting portion being characterized in that: a connecting component has a first end and a second end, the second end is through the connecting portion at the edge of the protecting case, the second end exposes at the outer surface of the connecting portion, the shape of the first end fits the inner surface of the connecting portion, so that the first end and the inner surface can be tightly fit to each other; and an anti-shedding band is through the second end at the connecting portion.

The current application is a continuation-in-part of, and claims a priority to Ser. No. 13/041,530 filed on Mar. 7, 2011.

### BACKGROUND OF THE INVENTION

1. Field of the Invention

The present invention generally relates to an anti-shedding structure for a tablet PC, more particularly to an anti-shedding structure that avoids the conditions of falling the tablet PC down while in operation and scratching the back surface of the tablet PC.

2. Description of the Prior Art

Slimness becomes the main stream for electronics nowadays. The most representative is tablet PC, and it obviously affects the market of laptop and gradually replaces laptop. Since the touch screen and slimness, operations to traditional laptop and other portable electronics have been totally changed. Tablet PC features that of easy operation and carry-on, and can be operated by only a single hand.

For avoiding careless falling down, the applicant had applied an American patent application on Mar. 3, 2011, and the application is titled as ANTI-SHEDDING STRUCTURE FOR TABLET PC and numbered as Ser. No. 13/041,530. The anti-shedding structure comprises: a protection device, which wraps around the back side of a tablet PC; and at least one anti-shedding band, which is at one side of the protective device; the anti-shedding band can be worn on a part of a user hand between the thumb and the index finger or the back of the user hand, in other words, the tablet PC can be operated by only one single hand and careless falling the tablet PC down can be avoided as well.

Due to the tendency and principle of slimness to tablet PC, a protecting device wrapping around the back side of the tablet PC must be a slim case. Such slim case is normally close to the back surface of the tablet PC, so that the slim case is coherent to the back surface of the tablet PC. Hence, the scratching problem between the slim case and the tablet PC due to frictions may be solved. To install an anti-shedding band on the slime case but not damage the coherence between the slime case and the tablet PC is the issue that the present invention will discuss.

### SUMMARY OF THE INVENTION

The present invention provides an anti-shedding structure for a tablet PC, which is to avoid falling while in careless. Further, the anti-shedding structure is coherent to the back surface of the tablet PC so as to avoid that the back surface is scratched.

A preferred embodiment of the anti-shedding structure for the tablet PC of the present invention comprises: a protecting case, having a bottom, the edge or corners of the bottom having a plurality of fastening portions, the edge of the protecting case having a connecting portion, the shape of the inner surface of the connecting portion fitting the shape of the back surface of the tablet PC, the connecting portion being characterized in that: a connecting component has a first end and a second end, the second end of the connecting component is through the connecting portion at the edge of the protecting case, the second end exposes at the outer surface of the connecting portion, the shape of the first end of the connecting component fits the inner surface of the connecting portion, so that the first end of the connecting component and the inner surface of the connecting portion can be tightly fit to each other; and an anti-shedding band is through the second end of the connecting component at the connecting portion in order to dispose the anti-shedding band outside of the connecting portion of the protecting case.

According to a preferred embodiment of the anti-shedding structure for the tablet PC of the present invention, the connecting portion comprises a left connecting portion and a right connecting portion that respectively connect with the connecting component at the two ends of the anti-shedding band.

According to a preferred embodiment of the anti-shedding structure for the tablet PC of the present invention, the connecting component penetrating through the connecting portion is a metal button or a plastic button.

According to a preferred embodiment of the anti-shedding structure for the tablet PC of the present invention, the connecting component penetrating through the connecting portion is a copper fastener or a plastic plug that rivets the anti-shedding band.

The anti-shedding band can be worn on a part of a user hand between the thumb and the index finger or the back of the user hand for avoiding falling down. On the other hand, the anti-shedding band is fastened on the connecting portion via the connecting component that goes through the connecting portion, the shape of the inner surface of the connecting portion fits the shape of the back surface of the tablet PC, the shape of the first end of the connecting component fits the inner surface of the connecting portion, so that the first end of the connecting component and the inner surface of the connecting portion can be tightly fit to each other, so that the back surface of the tablet PC being scratched by the connecting component can be avoided.

Other and further features, advantages, and benefits of the invention will become apparent in the following description taken in conjunction with the following drawings. It is to be understood that the foregoing general description and following detailed description are exemplary and explanatory but are not to be restrictive of the invention. The accompanying drawings are incorporated in and constitute a part of this application and, together with the description, serve to explain the principles of the invention in general terms. Like numerals refer to like parts throughout the disclosure.

### BRIEF DESCRIPTION OF THE DRAWINGS

The objects, spirits, and advantages of the preferred embodiments of the present invention will be readily understood by the accompanying drawings and detailed descriptions, wherein:

FIG. 1 illustrates a schematic 3-D structural view of an embodiment of an anti-shedding structure for a tablet PC of the present invention;

FIG. 2 illustrates a schematic sectional view of a section II-II in FIG. 1 and presents the relationships of a connecting portion, a connecting component and an anti-shedding band;

FIG. 3 illustrates a sectional amplified view of FIG. 2, and presents the relationships of the connecting portion, the connecting component and the anti-shedding band;

FIG. 4 illustrates a schematic 3-D structural view of another is embodiment of the anti-shedding structure for the tablet PC of the present invention, wherein the connecting portion has a left connecting portion and a right connecting portion;

FIG. 5 illustrates a schematic operation view of the anti-shedding structure for the tablet PC of the present invention, and presents that a hand goes through an anti-shedding band; and

FIG. 6 illustrates a schematic 3-D structural view of another embodiment of the anti-shedding structure for the tablet PC of the present invention, wherein a protecting case has a top cover.

### DETAILED DESCRIPTION OF THE INVENTION

Following preferred embodiments and figures will be described in detail so as to achieve aforesaid objects.

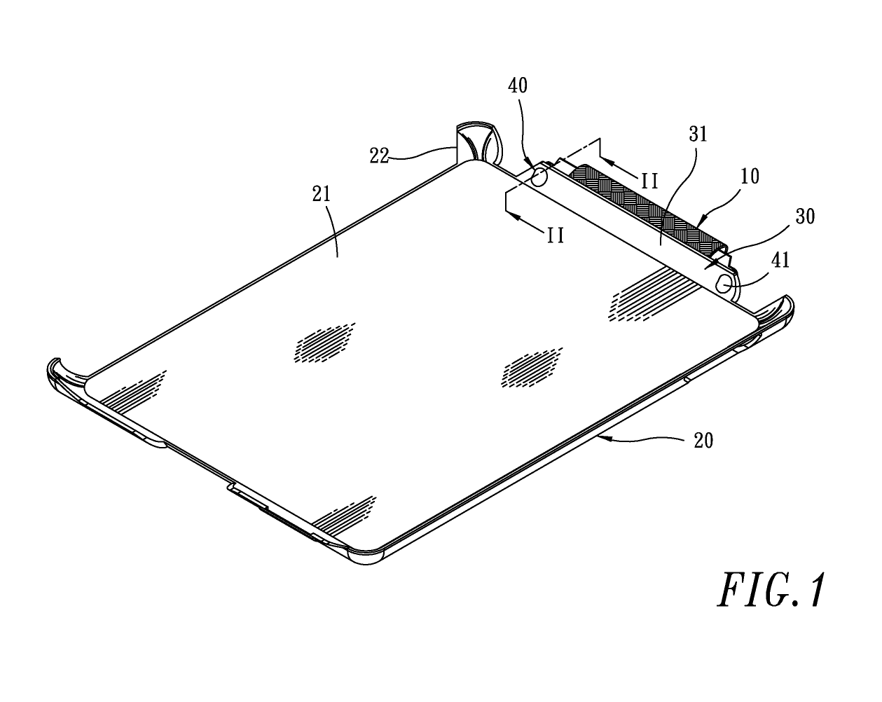

With reference to FIG. 1, which illustrates a schematic structural view of an embodiment of the anti-shedding structure for a tablet PC of the present invention. As shown in figure, the anti-shedding structure includes:

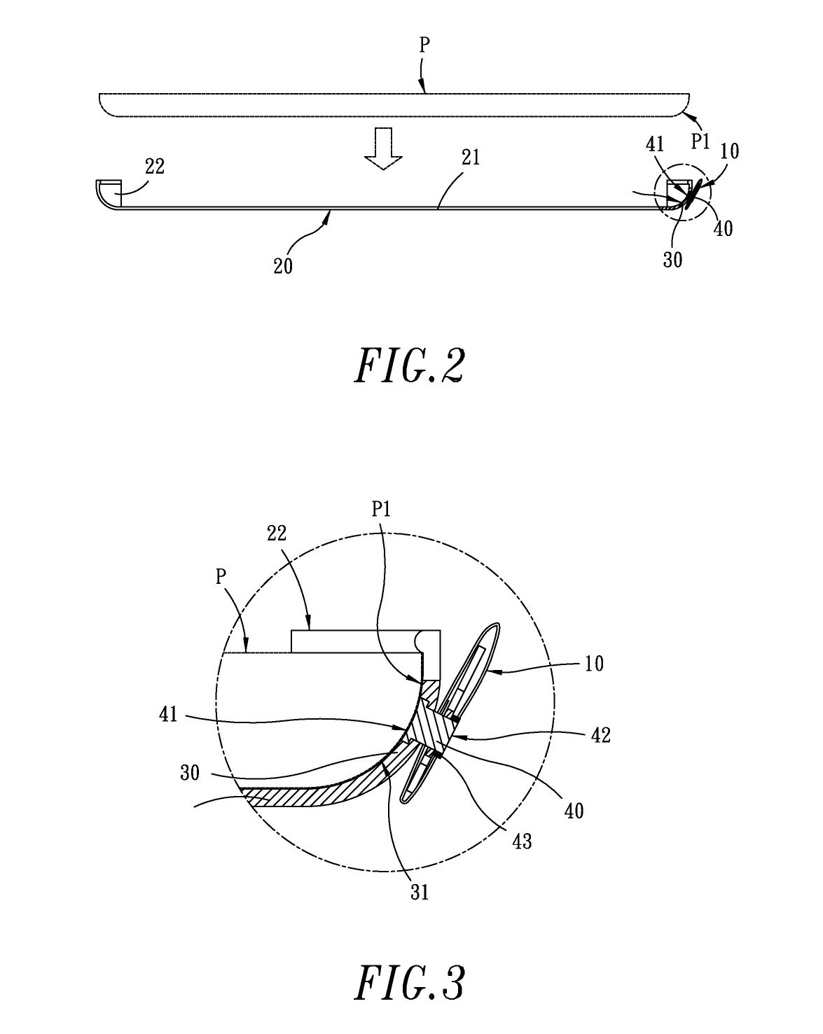

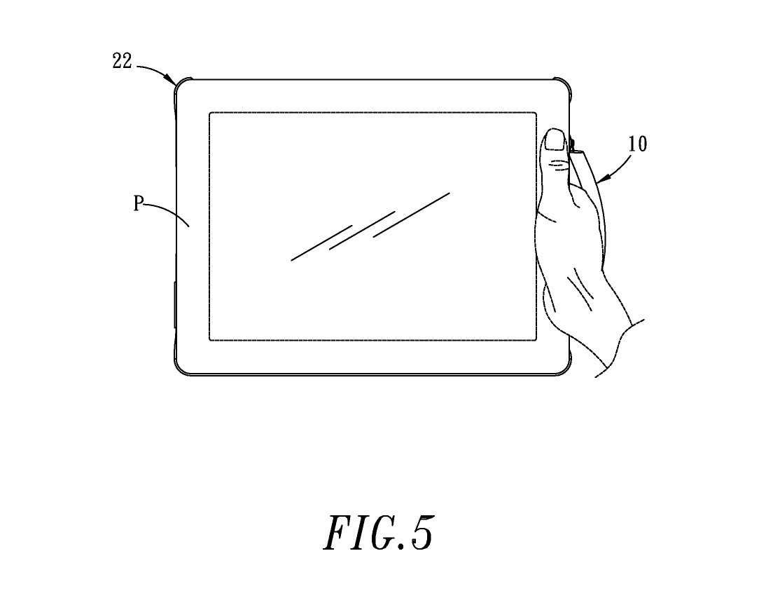

an anti-shedding band 10, which is a strip and flexible component and made of woven materials, artificial leather or natural leather; and
a protecting case 20, which is disposed at the back surface P1 of the tablet PC P for absorbing impact forces, as shown in FIG. 2. At least one edge of the protecting case 20 is disposed the anti-shedding band 10 that is worn on a part of a user hand between the thumb and the index finger or the back of the user hand for avoiding falling down, as shown in FIG. 5.

Since different brands of tablet PCs are with different dimensions and appearances, therefore the dimension and appearance of the protecting case 20 may be vary. The protecting case 20 disclosed by FIG. 1 is only an embodiment and may not restrict the scope of the present invention. With reference to FIG. 1, the protecting case 20 has a bottom 21, the edge or corners of the bottom 21 have a plurality of fastening portions 22 that fastens the edge of the tablet PC P. For a structure of the fastening portion 22, the top of the fastening portion 22 slightly bends toward the center of the bottom 21. While the tablet PC P is disposed on the bottom 21 of the protecting case 20, the fastening portions 22 hooks the tablet PC P. However, the fastening portions holding the tablet PC is one of the embodiments, and people skilled in the art may have other structures that achieve the same function.

According to a preferred embodiment of the anti-shedding structure for the tablet PC, the advanced part may describe as below: the edge of the bottom 21 of the protecting case 20 has a connecting portion 30, as shown in FIG. 2, the connecting portion 30 is a sheet structure extending outwardly from the edge of the bottom 21, the shape of the inner surface 31 of the connecting portion 30 fits the shape of the back surface P1 of the tablet PC P, the first end 41 of the connecting component 40 can be disposed in the connecting portion 30, as shown in FIG. 3, the shape of the first end 41 of the connecting component 40 fits the inner surface 31 of the connecting portion 30 for avoiding that the connecting component 40 scratches the back surface P1 of the tablet PC P.

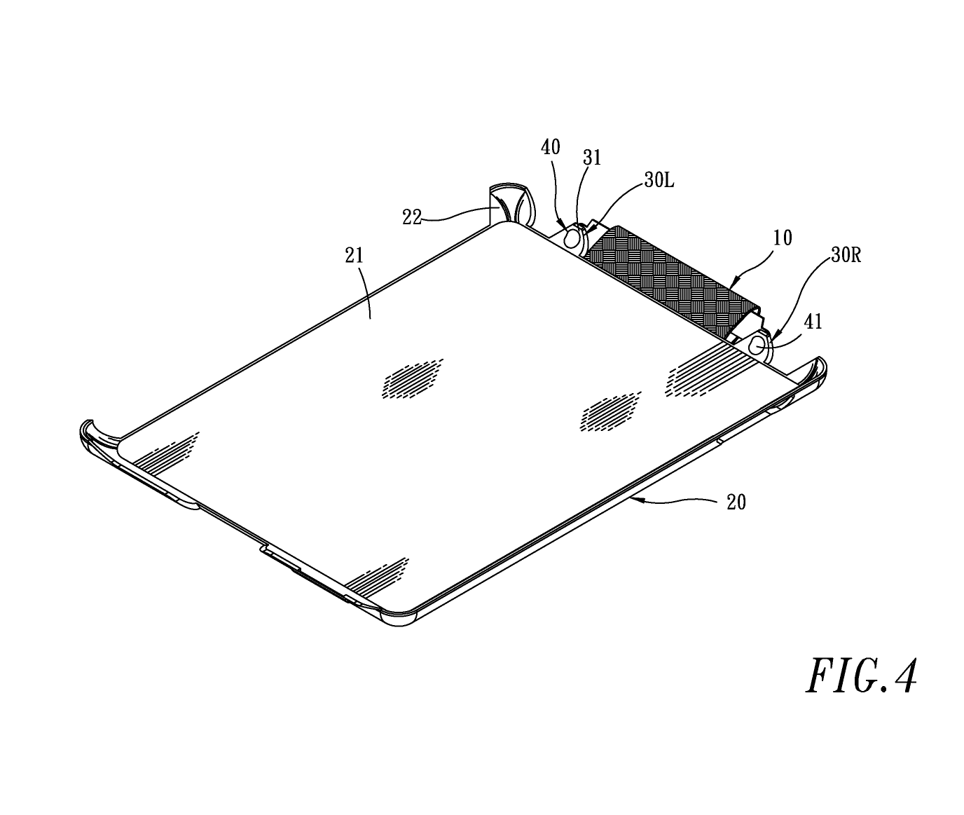

According to another preferred embodiment of the anti-shedding structure for the tablet PC, the connecting portion 30 is a single sheet structure, as shown in FIG. 1, two ends of the anti-shedding band 10 are fastened on the connecting portion 30 via the connecting component 40 that goes through the connecting portion 30. Another embodiment shown in FIG. 4, the connecting portion 30 is a two-piece sheet structure, in another word, a left connecting portion 30L and a right connecting portion 30R are respectively at the same edge of the bottom 21 of the protecting case 20, two ends of the anti-shedding band 10 respectively connect with the left connecting portion 30L and the right connecting portion 30R by means of the connecting component 40.

According to another preferred embodiment of the anti-shedding structure for the tablet PC, wherein the connecting component 40 penetrating through the connecting portion 30 is a metal button or a plastic button, or a copper fastener or a plastic plug that rivets the anti-shedding band 10, the second end 42 of the connecting component 40 goes through the anti-shedding band 10 and fastens with the anti-shedding band 10, the practical way is to use plural rivets 43 or adhesion, hence the second end 42 of the connecting component 40 may be fastened with the anti-shedding band 10, wherein the shape of the inner surface 31 of the connecting portion 30 fits the shape of the back surface P1 of the tablet PC P, the first end 41 of the connecting component 40 can be disposed in the connecting portion 30, the shape of the first end 41 of the connecting component 40 fits the inner surface 31 of the connecting portion 30, so that the first end 41 of the connecting component 40 and the inner surface 31 of the connecting portion 30 can be tightly fit to each other, as shown in FIG. 2, the inner surface 31 of the connecting portion 30 is an arc surface, the shape of the first end 41 of the connecting component 40 is an arc surface as well, so that the first end 41 of the connecting component 40 and the inner surface 31 of the connecting portion 30 can be tightly fit to each other for avoiding that the connecting component 40 scratches the back surface P1 of the tablet PC P.

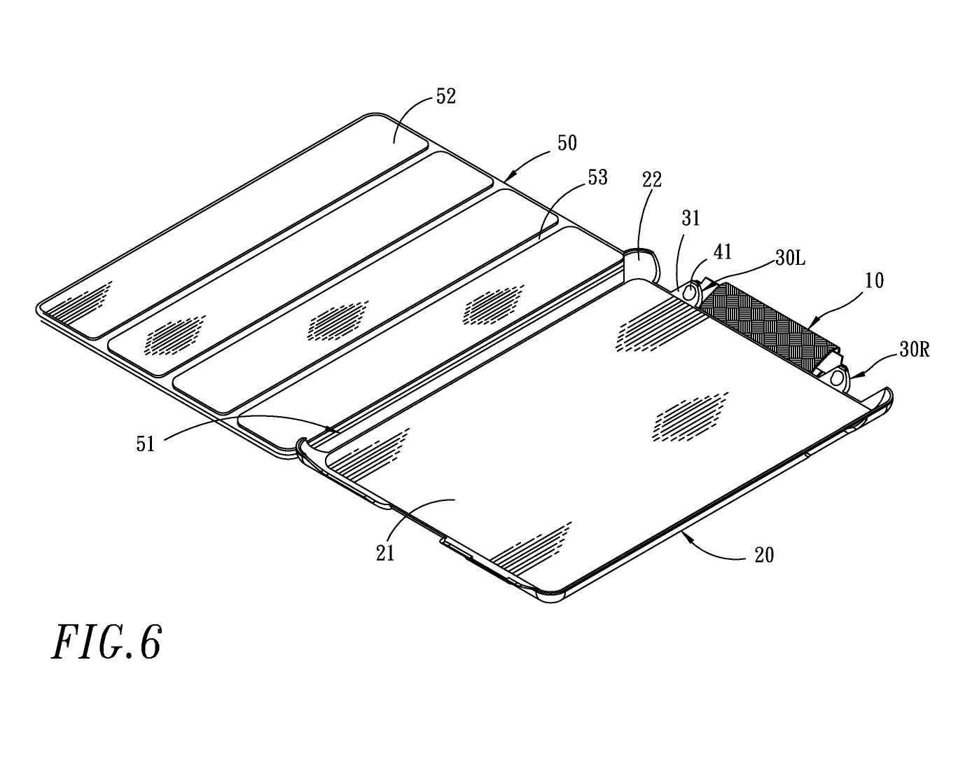

FIG. 6 presents another preferred embodiment of the present invention. The embodiment includes a top cover 50, one side of the top cover 50 has a connecting portion 50 that connects with the top cover 50, the top cover 50 has a plurality of sheet members 52 that connect with each other, a strip concave portion 53 is between every two sheet members 52 in order to roll the top cover 50 for supporting the protecting case 20 and the tablet PC P in a suitable view angle, additionally, the top cover 50 can be flipped over to cover on the tablet PC P for protection.

Although the invention has been disclosed and illustrated with reference to particular embodiments, the principles involved are susceptible for use in numerous other embodiments that will be apparent to persons skilled in the art. This invention is, therefore, to be limited only as indicated by the scope of the appended claims

What is claimed is:

1. An anti-shedding structure for a tablet PC comprising:
a protecting case, having a bottom, the edge or corners of the bottom having a plurality of fastening portions, the edge of the protecting case having a connecting portion, the shape of the inner surface of the connecting portion fitting the shape of the back surface of the tablet PC, the connecting portion being characterized in that:
a connecting component has a first end and a second end, the second end of the connecting component is through the connecting portion at the edge of the protecting case, the second end exposes at the outer surface of the connecting portion, the shape of the first end of the connecting component fits the inner surface of the connecting portion, so that the first end of the connecting component and the inner surface of the connecting portion can be tightly fit to each other; and
an anti-shedding band is through the second end of the connecting component at the connecting portion in order to dispose the anti-shedding band outside of the connecting portion of the protecting case.

2. The anti-shedding structure for the tablet PC according to claim 1, wherein the connecting portion comprises a left connecting portion and a right connecting portion that respectively connect with the connecting component at the two ends of the anti-shedding band.

3. The anti-shedding structure for the tablet PC according to claim 1, wherein the connecting component penetrating through the connecting portion is a metal button or a plastic button.

4. The anti-shedding structure for the tablet PC according to claim 1, wherein the connecting component penetrating through the connecting portion is a copper fastener or a plastic plug that rivets the anti-shedding band.

5. The anti-shedding structure for the tablet PC according to claim 1, wherein the first end of the connecting component can be disposed in the connecting portion.

6. The anti-shedding structure for the tablet PC according to claim 1, wherein the inner surface of the connecting portion of the protecting case is an arc surface, the shape of the first end of the connecting component being an arc surface as well, so that the first end of the connecting component and the inner surface of the connecting portion can be tightly fit to each other for avoiding that the connecting component scratches the back surface of the tablet PC.
